(19) United States
(12) Patent Application Publication
(10) Pub. No.: US 2013/0083492 A1
(43) Pub. Date: Apr. 4, 2013

(54) POWER MODULE PACKAGE AND METHOD OF MANUFACTURING THE SAME

(71) Applicants: Kwang Soo KIM, Gyeonggi-do (KR); Young Ki LEE, Gyeonggi-do (KR); Sung Keun PARK, Gyeonggi-do (KR); Seog Moon CHOI, Seoul (KR)

(72) Inventors: Kwang Soo KIM, Gyeonggi-do (KR); Young Ki LEE, Gyeonggi-do (KR); Sung Keun PARK, Gyeonggi-do (KR); Seog Moon CHOI, Seoul (KR)

(73) Assignee: SAMSUNG ELECTRO-MECHANICS CO., LTD, Suwon (KR)

(21) Appl. No.: 13/603,722

(22) Filed: Sep. 5, 2012

(30) Foreign Application Priority Data
Sep. 30, 2011 (KR) 10-2011-0099535

(51) Int. Cl. H05K 7/00; H05K 3/10

(52) U.S. Cl. 361/728; 29/846

(57) ABSTRACT

A power module package includes: a substrate having a stepped portion and a non-stepped portion; a power circuit unit electrically connected to a circuit wiring provided in the stepped portion; a control circuit unit electrically connected to a circuit wiring provided in the non-stepped portion; and a molding unit molded on the substrate to seal the power circuit unit while exposing the circuit wiring of the non-stepped portion. Therefore, it is possible to improve thermal characteristics of the power module package, implement high reliability between the power circuit unit and the control circuit unit, improve design freedom of the power module package, and implement miniaturization of products.

### CROSS-REFERENCE TO RELATED APPLICATIONS

This application claims the benefit under 35 U.S.C. Section 119 of Korean Patent Application Serial No. 10-2011-0099535, filed Sep. 30, 2011, which is hereby incorporated by reference in its entirety into this application.

### BACKGROUND OF THE INVENTION

1. Field of the Invention

The present invention relates to a power module package, and more particularly, to a power module package capable of providing excellent thermal characteristics, implementing high reliability between a power circuit unit and a control circuit unit, improving freedom of module design, and implementing miniaturization, and a method of manufacturing the same.

2. Description of the Related Art

As the amount of energy consumed increases around the world, there has been a lot of interest in efficient use of limited energy.

Accordingly, in existing consumer or industrial products, employment of an inverter using an intelligent power module (IPM) for efficient conversion of energy has been accelerated.

According to the extended application of the power module, there is a market demand for high integration, high capacity, and miniaturization of products. Accordingly, since heat generation of electronic components causes performance degradation of the entire module, a high heat-radiating and highly integrated power module package structure, which can effectively overcome the heat generation, is necessary to secure increased efficiency and high reliability of the power module.

Hereinafter, a power module package in accordance with the prior art will be described in detail with reference to the accompanying FIGS. 1 and 2.

First, a power module package shown in FIG. 1 as an example of the power module package in accordance with the prior art is configured by positioning a power device 11 such as an IGBT or a diode with high heat generation on a heat-radiating substrate 12 and connecting a printed circuit board (PCB), on which a control circuit unit is positioned, through a connecting unit 13 such as a metal cylinder or a connector to connect the power device to the control circuit unit.

However, this structure has difficulty in connecting the control circuit unit by the connecting unit such as the metal cylinder or connector. Accordingly, there are problems that the entire manufacturing process of the power module package is difficult, manufacturing costs of the power module package are increased, and electrical connection between the PCB of the control circuit unit and the connecting unit is weak in terms of reliability.

Next, as another example of the power module package in accordance with the prior art, in FIG. 2, a method of connecting a power circuit unit 21 to a control circuit unit 22 and passive devices 23 is disclosed. However, since the power circuit unit 21 is modularized and separately manufactured and bonded on a PCB 24, on which a driving device is positioned, by soldering, there are problems that a size of the power module package is increased and freedom of circuit design is greatly reduced.

### SUMMARY OF THE INVENTION

The present invention has been invented in order to overcome the above-described problems and it is, therefore, an object of the present invention to provide a power module package capable of providing excellent thermal characteristics and implementing high reliability between a power circuit unit and a control circuit unit, and a method of manufacturing the same.

It is another object of the present invention to provide a power module package capable of improving freedom of module design and implementing miniaturization, and a method of manufacturing the same.

In accordance with one aspect of the present invention to achieve the object, there is provided a power module package including: a substrate having a stepped portion and a non-stepped portion; a power circuit unit electrically connected to a circuit wiring provided in the stepped portion; a control circuit unit electrically connected to a circuit wiring provided in the non-stepped portion; and a molding unit molded on the substrate to seal the power circuit unit while exposing the circuit wiring of the non-stepped portion.

Here, the substrate may be made of a metal material having a heat-radiating property.

At this time, the metal may include aluminum.

The power module package may further include an insulating layer provided on a surface of the substrate.

Here, the insulating layer may include an aluminum oxide layer formed by anodizing.

At this time, the insulating layer may be formed with a thickness of 20 to 200 μm.

Meanwhile, the stepped portion may be formed by chemical processing including etching or mechanical processing including polishing.

At this time, the stepped portion may be formed with a thickness of 10 μm to 2 mm from the surface of the substrate.

Meanwhile, the circuit wiring may include a metal pad, and the circuit wiring including the metal pad may be formed by forming a metal layer on the surface of the substrate and performing etching or lift-off on the metal layer.

Here, the metal layer may be formed by dry sputtering or wet plating and made of one of Cu, Cu/Ni, Cu/Ti, Au/Pt/Ni/Cu, and Au/Pt/Ni/Cu/Ti.

And, the circuit wiring may be formed with a thickness of 10 to 300 μm.

Meanwhile, the power circuit unit may include a power device, and the power device may be directly bonded to the circuit wiring provided in the stepped portion or bonded to a lead frame electrically connected to the circuit wiring.

At this time, the power device may be electrically connected to the circuit wiring and the lead frame through a wire.

And, the control circuit unit may include a printed circuit board and a control device electrically connected to the printed circuit board.

Here, an external connection means may be provided on the printed circuit board, and the control circuit unit may be electrically connected to the circuit wiring provided in the non-stepped portion by the external connection means.

At this time, the external connection means may include a ball grid array (BGA).

Further, the external connection means may be provided in one end portion of the printed circuit board, and the other end portion of the printed circuit board may be disposed on a surface of the molding unit above the power circuit unit.

At this time, the other end portion of the printed circuit board may be supported to the surface of the molding unit by a spacer or a metal post.

Further, an insertion groove may be formed on the surface of the molding unit, and as the spacer and the metal post are coupled with the insertion groove, the other end portion of the printed circuit board may be fixed and supported to the molding unit.

In accordance with another aspect of the present invention to achieve the object, there is provided a method of manufacturing a power module package including: (a) forming a stepped portion and a non-stepped portion in a substrate; (b) forming circuit wirings, which are electrically connected to each other, in the stepped portion and the non-stepped portion; (c) electrically connecting a power circuit unit to the circuit wiring provided in the stepped portion; (d) molding the power circuit unit while exposing the circuit wiring of the non-stepped portion; and (e) electrically connecting a control circuit unit to the circuit wiring of the non-stepped portion.

Here, the stepped portion may be formed by performing chemical processing or mechanical processing.

The method of manufacturing a power module package may further include, after the step (a), forming an insulating layer on a surface of the substrate.

At this time, the insulating layer may be formed through a process of forming an Al₂O₃ oxide layer on the surface of the substrate by anodizing.

Meanwhile, the step (e) may include electrically connecting one end portion of the control circuit unit to the circuit wiring of the non-stepped portion by an external connection means and supporting the other end portion of the control circuit unit to a surface of the molding unit above the power circuit unit by a spacer or a metal post.

At this time, the space and the metal post may be fixed by being coupled with an insertion groove formed on the surface of the molding unit.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view schematically showing an example of a power module package in accordance with the prior art;

FIG. 2 is a cross-sectional view schematically showing another example of the power module package in accordance with the prior art;

FIG. 3 is a cross-sectional view schematically showing a first embodiment of a power module package of the present invention;

FIGS. 4A to 4H are process cross-sectional views for explaining a process of manufacturing the power module package of FIG. 3;

FIG. 5 is a cross-sectional view schematically showing a second embodiment of the power module package of the present invention;

FIG. 6 is a cross-sectional view schematically showing a third embodiment of the power module package of the present invention; and

FIG. 7 is a cross-sectional view schematically showing an example in which a metal post is applied to the power module package of FIG. 6 instead of a spacer.

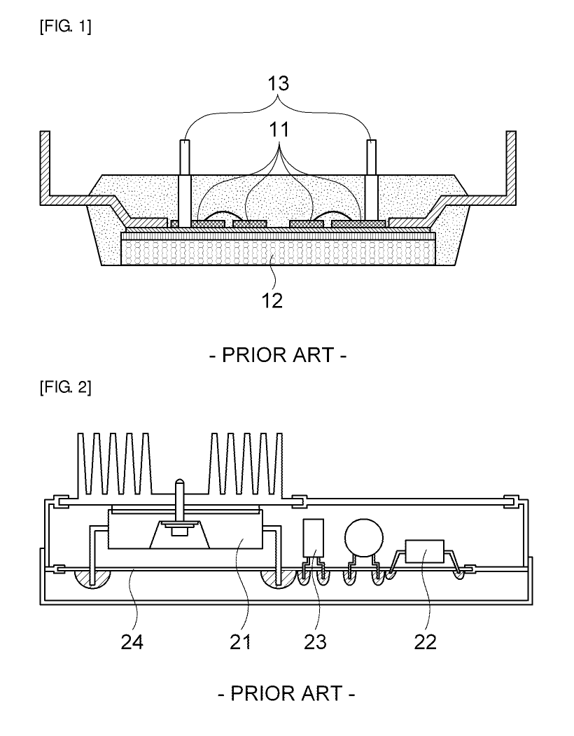

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Further, embodiments to be described throughout the specification will be described with reference to cross-sectional views and/or plan views, which are ideal exemplary drawings of the present invention. In the drawings, the thicknesses of layers and regions may be exaggerated for the effective explanation of technical contents. Therefore, the exemplary drawings may be modified by manufacturing techniques and/or tolerances. Therefore, the embodiments of the present invention are not limited to the accompanying drawings, and can include modifications to be generated according to manufacturing processes. For example, an etched region shown at a right angle may be formed in the rounded shape or formed to have a predetermined curvature. Therefore, regions shown in the drawings have schematic characteristics. In addition, the shapes of the regions shown in the drawings exemplify specific shapes of regions in an element, and do not limit the invention.

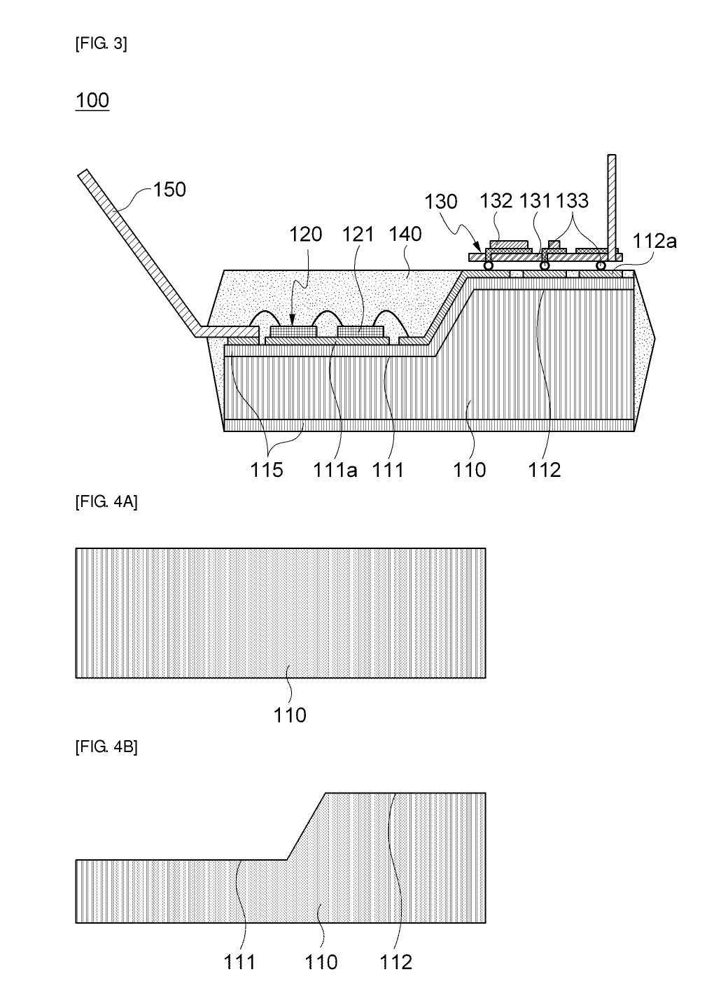

Hereinafter, embodiments of a power module package and a method of manufacturing the same in accordance with the present invention will be described in detail with reference to the accompanying FIGS. 3 to 7.

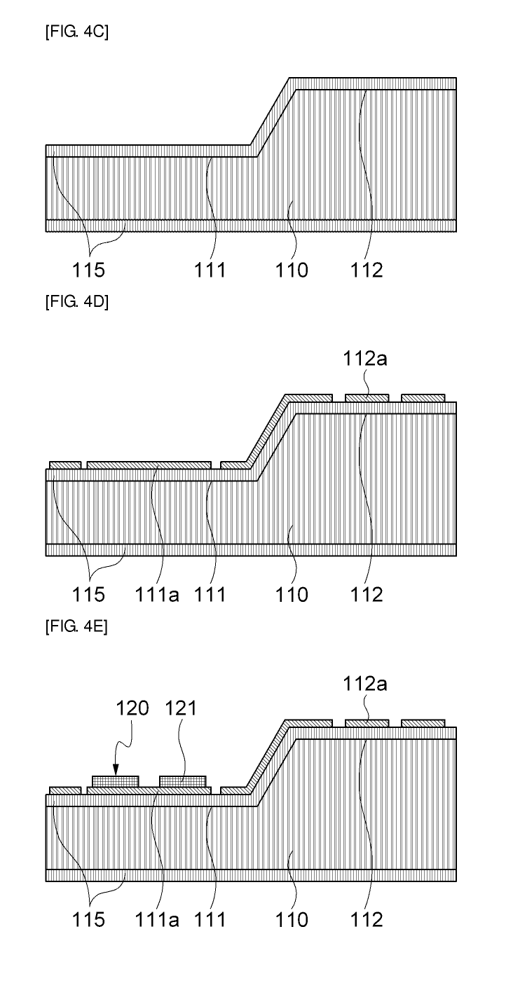

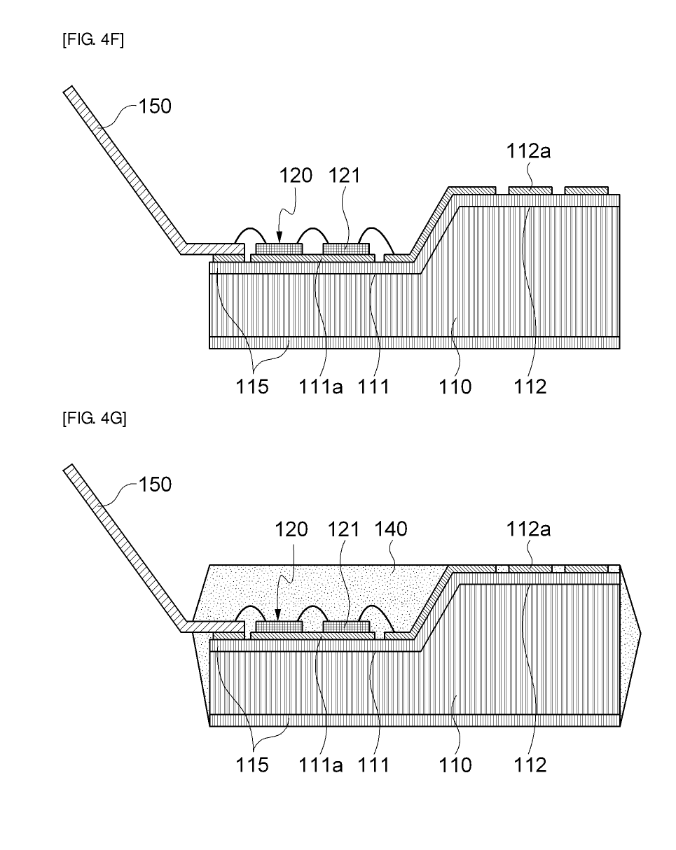

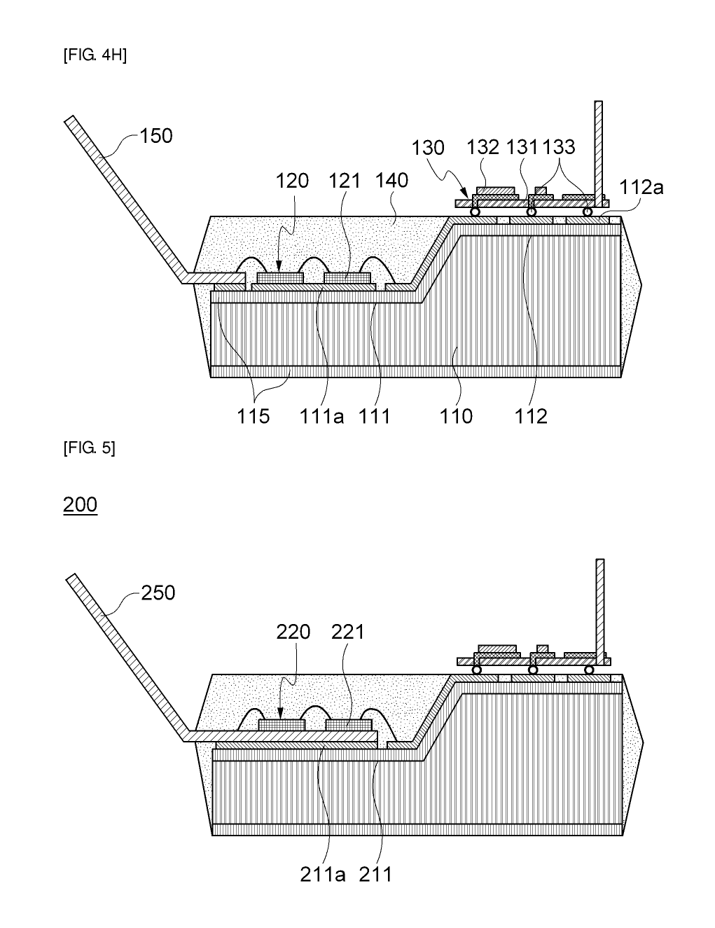

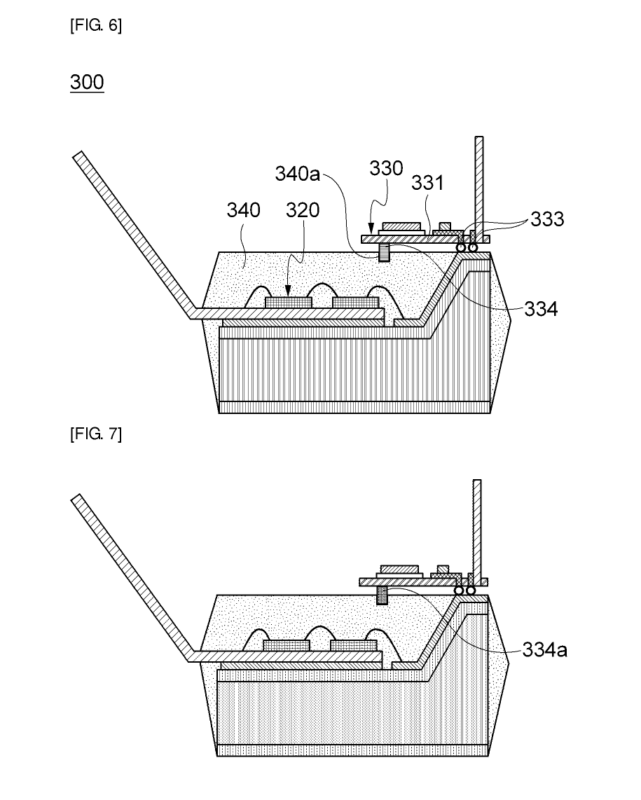

FIG. 3 is a cross-sectional view schematically showing a first embodiment of a power module package of the present invention. FIGS. 4A to 4H are process cross-sectional views for explaining a process of manufacturing the power module package of FIG. 3. FIG. 5 is a cross-sectional view schematically showing a second embodiment of the power module package of the present invention. FIG. 6 is a cross-sectional view schematically showing a third embodiment of the power module package of the present invention. FIG. 7 is a cross-sectional view schematically showing an example in which a metal post is applied to the power module package of FIG. 6 instead of a spacer.

First, a first embodiment of a power module package in accordance with the present invention will be described with reference to FIGS. 3 to 4H.

Referring to FIG. 3, a first embodiment 100 of a power module package in accordance with the present invention includes a substrate 110, a power circuit unit 120, a control circuit unit 130, and a molding unit 140.

A stepped portion 111 and a non-stepped portion 112 may be formed in the substrate 110.

Here, the substrate 110 may be made of a metal material having a heat-radiating property.

At this time, the metal may include aluminum.

And, the stepped portion 111 may be formed by chemical processing including etching or mechanical processing including polishing. Accordingly, the non-stepped portion 112 may be a portion of the substrate 110, where the stepped portion 111 is not formed.

At this time, the stepped portion 111 may be formed with a thickness of 10 μm to 2 mm from a surface of the substrate 110 according to the structure and packaging process of the power circuit unit 120.

The power module package 100 in accordance with this embodiment may further include an insulating layer 115 provided on the surface of the substrate 110.

Here, the insulating layer 115 may include Al₂O₃, that is, an aluminum oxide layer formed by anodizing.

At this time, the insulating layer 115, that is, the aluminum oxide layer may be formed with a thickness of 20 to 200 μm according to the purpose and heat-radiating characteristics.

A circuit wiring 111a formed in, the stepped portion 111 and a circuit wiring 112a formed in the non-stepped portion 112 may be patterned to have mutual electrical connection.

Here, the circuit wirings 111a and 112a may include metal pads and may be formed by forming a metal layer on the surface of the substrate 110 and performing a typical etching process on the metal layer.

At this time, the circuit wirings 111a and 112a may be formed by patterning the metal layer through a lift-off process other than the typical etching process. The lift-off process belongs to the case in which patterning is performed without typical etching, among the etching processes of semiconductor processes and is a method of forming a pattern by performing PR patterning before film deposition, performing film deposition thereon, and removing PR.

Here, the metal layer may be made of one metal of Cu, Cu/Ni, Cu/Ti, Au/Pt/Ni/Cu, and Au/Pt/Ni/Cu/Ti, and the metal may be formed by performing dry sputtering or wet electro/electroless plating.

And, the circuit wirings 111a and 112a may be appropriately selectively formed with a thickness of 10 to 300 μm according to the structure and manufacturing process of the package.

The power circuit unit 120 may be electrically connected to the circuit wiring 111a provided in the stepped portion 111.

Here, the power circuit unit 120 may include a power device 121, and the power device 121 may be fixed by being directly bonded to the circuit wiring 111a provided in the stepped portion 111.

At this time, the power device 121 may be electrically connected to a lead frame 150 for electrically connecting the circuit wiring 111a of the stepped portion 111 and chips such as power devices to an external circuit board and the like through a wire.

The molding unit 140 may be formed by molding epoxy and the like on the substrate 110 to seal the power circuit unit 110 while exposing the circuit wiring 112a of the non-stepped portion 112.

The control circuit unit 130 may be electrically connected to the circuit wiring 112a provided in the non-stepped portion 112.

Here, the control circuit unit 130 may include a printed circuit board (PCB) 131 and a control device 132 electrically connected to the PCB 131.

And, an external connection means 133 may be provided on the PCB 131. Accordingly, the control circuit unit 130 may be electrically connected to the circuit wiring 112a provided in the non-stepped portion 112 by the external connection means 133.

That is, the control circuit unit 130 of this embodiment may be soldered on the circuit wiring 112a provided in the non-stepped portion 112 through the external connection means formed on the PCB in a state in which the control device is packaged on the PCB.

At this time, the external connection means 133 may include a ball grid array (BGA) but not limited thereto.

A method of manufacturing the power module package in accordance with this embodiment configured as above will be described below.

A method of manufacturing a power module package in accordance with this embodiment includes the steps of forming a stepped portion 111 and a non-stepped portion 112 in a substrate 110; forming circuit wirings 111a and 112a, which are electrically connected to each other, in the stepped portion 111 and the non-stepped portion 112; electrically connecting a power circuit unit 120 to the circuit wiring 111a provided in the stepped portion 111; molding the power circuit unit 120 while exposing the circuit wiring 112a of the non-stepped portion 112; and electrically connecting a control circuit unit 130 to the circuit wiring 112a of the non-stepped portion 112.

In more detail, as shown in FIG. 4A, the substrate 110 made of a metal material such as aluminum is prepared after being processed with desired thickness and size in consideration of the stepped portion, the power circuit unit, and the control circuit unit.

And, as shown in FIG. 4B, the stepped portion 111 is formed by processing a portion of the substrate 110. At this time, the stepped portion 111 may be formed by performing chemical processing or mechanical processing, and a portion which is not processed into the stepped portion 111 may be relatively formed into the non-stepped portion 112.

Next, as shown in FIG. 4C, an insulating layer 115 is formed on a surface of the substrate 110. Here, the insulating layer 115 may be formed through a process of forming an Al₂O₃ oxide layer on the surface of the substrate 110 by anodizing.

And, as shown in FIG. 4D, the circuit wirings 111a and 112a are formed in the stepped portion 111 and the non-stepped portion 112.

Next, as shown in FIG. 4E, a power device 121 is fixed by being bonded to the circuit wiring 111a of the stepped portion 111.

And, as shown in FIG. 4F, a lead frame 150 is connected and bonded to a portion of the circuit wiring 111a of the stepped portion 111, and the power device 121 is electrically connected to the circuit wiring 111a of the stepped portion 111 and the lead frame 150 through a wire.

Next, as shown in FIG. 4G, a molding unit 140 is formed by molding epoxy and the like on the substrate 110. At this time, the molding unit 140 may be formed to expose the circuit wiring 112a of the non-stepped portion 112 while sealing the power circuit unit 120 including the power device 121.

And, as shown in FIG. 4F, the control circuit unit 130 is electrically connected to the circuit wiring 112a of the non-stepped portion 112. At this time, the control circuit unit 130 is fixed and electrically connected to the circuit wiring 112a provided in the non-stepped portion 112 by soldering an external connection means 133, which is formed on a PCB 131 of the control circuit unit 130, on the circuit wiring 112a provided in the non-stepped portion 112.

Next, a second embodiment of the power module package in accordance with the present invention will be described in detail with reference to FIG. 5.

As shown in FIG. 5, compared to the above-described first embodiment, a power module package 200 in accordance with this embodiment discloses that a power device 221 of a power circuit unit 220 is fixed by being bonded to a lead frame 250 electrically connected to a circuit wiring 211a provided in a stepped portion 211 instead of being directly bonded to the circuit wiring 211a provided in the stepped portion 211.

Accordingly, it is possible to improve reliability of the circuit unit by improving heat-radiating characteristics during operation of the power device 221 of the power circuit unit 220.

Since the power module package 200 in accordance with this embodiment has the same structure and manufacturing method as the above-described first embodiment except for a bonding structure and a bonding method of the power device 221 and the lead frame 250, detailed description of this will be omitted.

Next, a third embodiment of the power module package in accordance with the present invention will be described in detail with reference to FIG. 6.

As shown in FIG. 6, compared to the above-described first embodiment, a power module package 300 in accordance with this embodiment discloses that an external connection means 333 formed on a PCB 331 of a control circuit unit 330 is provided to be concentrated in one end portion of the PCB 331 and thus the other end portion of the PCB 331 is disposed on a surface of a molding unit 340 above a power circuit unit 320.

Accordingly, the power module package 300 in accordance with this embodiment can implement miniaturization of a product by disposing a portion of the control circuit unit 330 inside an upper portion of the power circuit unit 320 to reduce a horizontal size of the entire package.

Here, since the external connection means 333 is provided to be concentrated in one end portion of the PCB 331, the other end portion of the PCB 331 may be inclined downward or may not be fixed.

Therefore, a spacer 334 may be provided in the other end portion of the PCB 331 to fix and support the other end portion of the PCB 331 to the surface of the molding unit 340 while maintaining the level of the PCB 331.

At this time, the spacer 334 may be made of a non-metal substrate and the like and stably fixed by being coupled with an insertion groove 340a formed on the surface of the molding unit 340.

Meanwhile, as shown in FIG. 7, it is possible to improve a heat-radiating property of the control circuit unit though a metal post 334a by applying the metal post 334a made of a metal material instead of the spacer.

As described above, according to the power module package and the method of manufacturing the same in accordance with the present invention, it is possible to remarkably improve thermal characteristics of the power module package and implement high reliability between the power circuit unit and the control circuit unit by minimizing transmission of heat from the power circuit unit to the control circuit unit.

And, according to the power module package and the method of manufacturing the same in accordance with the present invention, it is possible to improve design freedom of the circuit unit of the power module package and implement miniaturization of a product such as reduction in horizontal size of the power module package.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. A power module package comprising:
a substrate having a stepped portion and a non-stepped portion;
a power circuit unit electrically connected to a circuit wiring provided in the stepped portion;
a control circuit unit electrically connected to a circuit wiring provided in the non-stepped portion; and
a molding unit molded on the substrate to seal the power circuit unit while exposing the circuit wiring of the non-stepped portion.

2. The power module package according to claim 1, wherein the substrate is made of a metal material having a heat-radiating property.

3. The power module package according to claim 2, wherein the metal comprises aluminum.

4. The power module package according to claim 1, further comprising:
an insulating layer provided on a surface of the substrate.

5. The power module package according to claim 4, wherein the insulating layer comprises an aluminum oxide layer formed by anodizing.

6. The power module package according to claim 4, wherein the insulating layer is formed with a thickness of 20 to 200 μm.

7. The power module package according to claim 1, wherein the stepped portion is formed by chemical processing including etching or mechanical processing including polishing.

8. The power module package according to claim 7, wherein the stepped portion is formed with a thickness of 10 μm to 2 mm from the surface of the substrate.

9. The power module package according to claim 1, wherein the circuit wiring comprises a metal pad, and the circuit wiring comprising the metal pad is formed by forming a metal layer on the surface of the substrate and performing etching or lift-off on the metal layer.

10. The power module package according to claim 9, wherein the metal layer is formed by dry sputtering or wet plating and made of one of Cu, Cu/Ni, Cu/Ti, Au/Pt/Ni/Cu, and Au/Pt/Ni/Cu/Ti.

11. The power module package according to claim 9, wherein the circuit wiring is formed with a thickness of 10 to 300 μm.

12. The power module package according to claim 1, wherein the power circuit unit comprises a power device, and the power device is directly bonded to the circuit wiring provided in the stepped portion or bonded to a lead frame electrically connected to the circuit wiring.

13. The power module package according to claim 12, wherein the power device is electrically connected to the circuit wiring and the lead frame through a wire.

14. The power module package according to claim 1, wherein the control circuit unit comprises a printed circuit board and a control device electrically connected to the printed circuit board.

15. The power module package according to claim 14, wherein an external connection means is provided on the printed circuit board, and the control circuit unit is electrically connected to the circuit wiring provided in the non-stepped portion by the external connection means.

16. The power module package according to claim 15, wherein the external connection means comprises a ball grid array (BGA).

17. The power module package according to claim 15, wherein the external connection means is provided in one end portion of the printed circuit board, and the other end portion of the printed circuit board is disposed on a surface of the molding unit above the power circuit unit.

18. The power module package according to claim 17, wherein the other end portion of the printed circuit board is supported to the surface of the molding unit by a spacer or a metal post.

19. The power module package according to claim 18, wherein an insertion groove is formed on the surface of the molding unit, and as the spacer and the metal post are coupled with the insertion groove, the other end portion of the printed circuit board is fixed and supported to the molding unit.

20. A method of manufacturing a power module package comprising:
forming a stepped portion and a non-stepped portion in a substrate;
forming circuit wirings, which are electrically connected to each other, in the stepped portion and the non-stepped portion;
electrically connecting a power circuit unit to the circuit wiring provided in the stepped portion;
molding the power circuit unit while exposing the circuit wiring of the non-stepped portion; and
electrically connecting a control circuit unit to the circuit wiring of the non-stepped portion.

21. The method of manufacturing a power module package according to claim 20, wherein the stepped portion is formed by performing chemical processing or mechanical processing.

22. The method of manufacturing a power module package according to claim 20, further comprising, after forming a stepped portion and a non-stepped portion in a substrate, forming an insulating layer on a surface of the substrate.

23. The method of manufacturing a power module package according to claim 22, wherein the insulating layer is formed through a process of forming an Al₂O₃ oxide layer on the surface of the substrate by anodizing.

24. The method of manufacturing a power module package according to claim 20, wherein the electrically connecting a control circuit unit to the circuit wiring of the non-stepped portion comprises electrically connecting one end portion of the control circuit unit to the circuit wiring of the non-stepped portion by an external connection means and supporting the other end portion of the control circuit unit to a surface of the molding unit above the power circuit unit by a spacer or a metal post.

25. The method of manufacturing a power module package according to claim 24, wherein the spacer and the metal post are fixed by being coupled with an insertion groove formed on the surface of the molding unit.
